(19) United States
(12) Patent Application Publication
(10) Pub. No.: US 2013/0012022 A1
(43) Pub. Date: Jan. 10, 2013

(54) METHOD FOR FABRICATING SILICON NANOWIRE ARRAYS

(75) Inventors: Yung-Jr Hung, Taipei City (TW); San-liang Lee, Taipei City (TW); Kai-Chung Wu, Taipei City (TW)

(73) Assignee: National Taiwan University of Science and Technology, Taipei City (TW)

(21) Appl. No.: 13/343,706

(22) Filed: Jan. 4, 2012

(30) Foreign Application Priority Data
Jul. 4, 2011 (TW) 100123562

(51) Int. Cl. H01L 21/28; B82Y 40/00

(52) U.S. Cl. 438/680; 438/597; 257/E21.158; 977/762

(57) ABSTRACT

A method for larger-area fabrication of uniform silicon nanowire arrays is disclosed. The method includes forming a metal layer with a predetermined thickness on a substrate whose surface has a silicon material by a coating process, the metal layer selected from the group consisting of Ag, Au and Pt; and performing a metal-induced chemical etching for the silicon material by using an etching solution. Accordingly, a drawback that Ag nanoparticles are utilized to perform the metal-induced chemical etching in prior art is solved.

### CROSS-REFERENCE

This application claims the priority of Taiwan Patent Application No. 100123562, filed on Jul. 4, 2011. This invention is partly disclosed in a conference “WTM 2011 IEEE Photonics Society Winter Topical Meeting on Low Dimensional Nanostructures and Sub-Wavelength Photonics, 10 Jan. 2011”, entitled “Aligned Silicon Nanowire Arrays for Achieving Black Nonreflecting Silicon Surface” completed by Yung-jr Hung, Kai-chung Wu, San-hang Lee.

### TECHNICAL FIELD OF THE INVENTION

The present invention relates to a method for fabricating silicon nanowires, especially to a method for larger-area fabrication of uniform silicon nanowire arrays.

### BACKGROUD OF THE INVENTION

Silicon nanowire (SiNW) arrays have an antireflective surface, and it can be applied to surfaces of solar cells for effectively enhancing the absorption of sunlight. Conventionally, the silicon nanowire (SiNW) arrays are fabricated by photolithigraphy processes. However, the manufacturing cost thereof is higher, and it is difficult to fabricate the silicon nanowire array with a large area such solar panels. As a result, fabrication method of the larger-area silicon nanowire arrays is gradually shifted to non-photolithigraphy processes, for example, the growth of silicon nanowires, a metal-induced silicon etching, and so on.

The conventional fabrication method of the larger-area silicon nanowire arrays by the metal-induced silicon etching is by immersing a silicon substrate in a solution with nano silver particles, for example, silver nitrate (AgNO₃) mixed in hydrofluoric acid (HF) solution, whereby the nano silver particles are deposited on the surface of the silicon substrate. Subsequently, a wet etching is performed for the silicon substrate which has the nano silver particles thereon. For instance, the silicon substrate having the nano silver particles is immersed in a solution of hydrofluoric acid (HF) and hydrogen peroxide (H₂O₂), in which the silver nano particles serve as catalysts for local silicon material having the nano silver particles thereon being partially etched. When it is etched down to a predetermined depth, the silicon substrate is taken out to stop etch. Finally, the silver nano particles are washed away by using nitric acid (HNO₃) for forming desired silicon nanowire array.

However, in fabricating the silicon nanowire arrays by the conventional metal-induced silicon etching, sizes and locations of deposited metal particles are random, so uniformity of the formed silicon nanowire array is not good and there is a clustering phenomenon occurred. Clustering phenomenon becomes serious as the silicon nanowires are longer. Therefore, it can not reach the objective of fabricating the silicon nanowire arrays with a large area and uniform arrangement.

Accordingly, there is an urgent need to improve the conventional technology to overcome the drawback in the conventional metal-induced silicon etching.

### SUMMARY OF THE INVENTION

An objective of the present invention is to provide a fabricating method of silicon nanowire arrays, which is by coating a ultra-thin metal layer on a substrate whose surface has a silicon material and then performing a metal-induced chemical etching for the silicon material. The silicon nanowire arrays with a large area and uniform arrangement can be fabricated by the method.

To achieve the foregoing objectives, a method provided by the present invention for fabricating the silicon nanowire arrays includes: forming a metal layer with a predetermined thickness on a substrate, whose surface has a silicon material by a coating process, the metal layer selected from the group consisting of silver, gold and platinum, wherein the substrate is a silicon substrate, a silicon substrate whose surface has a thin silicon film, or other substrate; performing a metal-induced chemical etching for the silicon material by using an etching solution; and rinsing the metal layer from the surface of the substrate.

In one preferred embodiment, the coating process is an electron beam evaporation, a physical vapor deposition, a chemical vapor deposition, or a sputtering. In the preferred embodiment, the metal layer is silver, and the predetermined thickness of the metal layer is between 5 and 50 nanometers. In addition, the etching solution is an aqueous solution of hydrogen fluoride and hydrogen peroxide, and a ratio of the hydrogen fluoride within the solution of the hydrogen fluoride and the hydrogen peroxide is 0.7 to 0.99. In the preferred embodiment, a silicon etching rate is proportional to a temperature of the etching solution. Furthermore, a length of silicon nanowires is proportional to an etching time under a predetermined temperature.

It is worth mentioning that the length of the formed silicon nanowires is smaller than or equal to an etching depth of the silicon material. The smaller an area of the metal layer on the silicon material is, the larger a difference between a length of the silicon nanowires and a total etching depth is, and an etching rate of forming the silicon nanowires also decreases.

In accordance with the method for fabricating the silicon nanowire arrays of the present invention, the conventional method for depositing the nano silver particles on the surface of the silicon substrate can be replaced by using the coating process to coat a ultra-thin silver layer for the silver naturally forming porous structure on the surface of the silicon substrate. Then the metal-induced chemical etching is performed for the silicon nanowire arrays with a large area and uniform arrangement being etched out.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 depicts a flow chart illustrating a method for fabricating silicon nanowire arrays according to the preferred embodiment of the present invention;

FIG. 2 depicts a schematic cross-sectional diagram illustrating a substrate whose surface has a silicon material in performing step S10;

FIG. 3 depicts a schematic cross-sectional diagram illustrating a substrate whose surface has a silicon material in performing step S20;

FIG. 4a is a top view through an electron microscope illustrating a etched silicon nanowire array under the ratio of the hydrogen fluoride within the solution of the hydrogen fluoride and the hydrogen peroxide being 0.89;

FIG. 4b is a side view of FIG. 4a;

FIG. 5a is a top view through an electron microscope illustrating a etched silicon nanowire array under the ratio of the hydrogen fluoride within the solution of the hydrogen fluoride and the hydrogen peroxide being 0.68;

FIG. 5b is a side view of FIG. 5a;

FIG. 6 is a schematic cross-sectional diagram illustrating the silicon nanowire array on different sizes of etching areas; and

FIG. 7 depicts a schematic cross-sectional diagram illustrating a substrate whose surface has a silicon material in performing step S30.

### DETAILED DESCRIPTION OF THE INVENTION

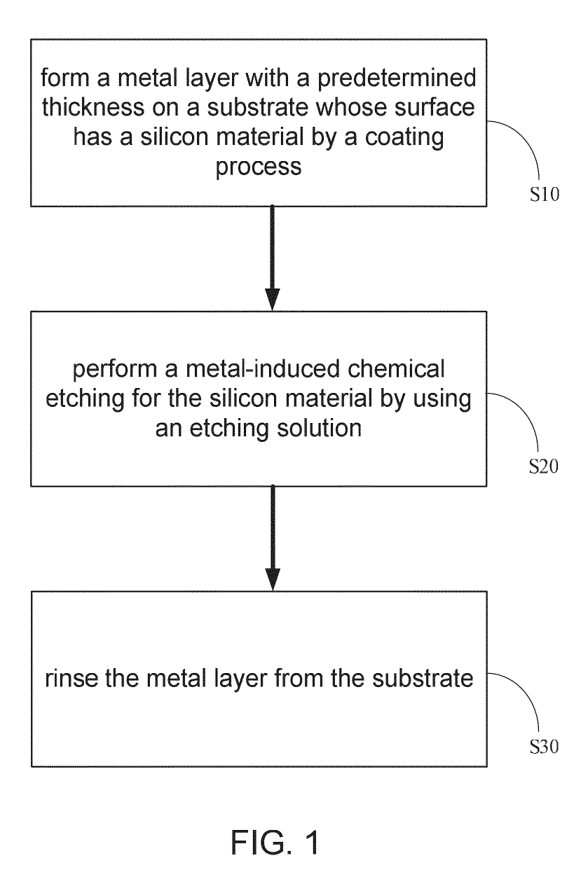

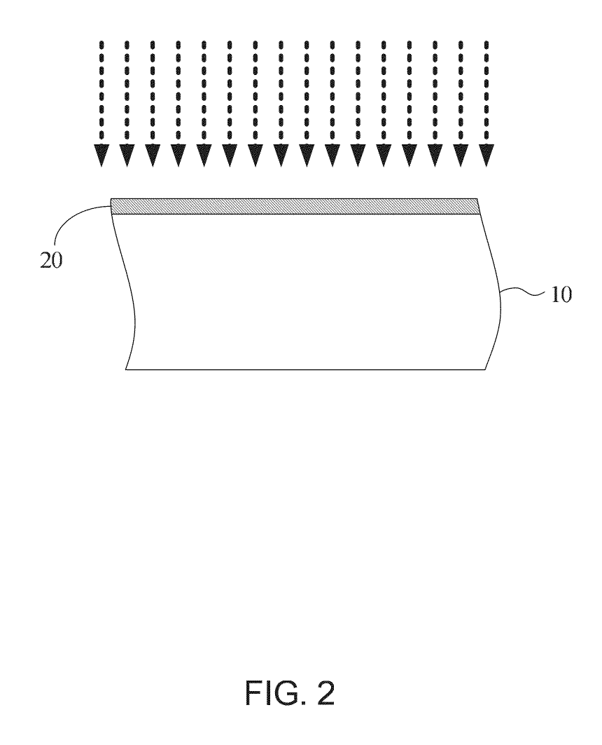

The following will explain a method for fabricating silicon nanowire arrays according to a preferred embodiment of the present invention in detail with drawings. Referring to FIG. 1 and FIG. 2, FIG. 1 depicts a flow chart illustrating a method for fabricating silicon nanowire arrays according to the preferred embodiment of the present invention, and FIG. 2 depicts a schematic cross-sectional diagram illustrating a substrate whose surface has a silicon material in performing step S10. The fabricating method is utilized to fabricate a silicon nanowire array with a high uniformity on a substrate whose surface has a silicon material, or substrate 10 for short. The silicon material herein can be a monocrystalline silicon, which has a lattice plane of (100), (110), or (111). The silicon material also can be a polycrystalline silicon or amorphous silicon (a-Si); moreover, the silicon material is intrinsic silicon or doped silicon.

At step S10, a metal layer 20 with a predetermined thickness is formed on a substrate 10 whose surface has the silicon material by a coating process. The metal layer 20 is selected from the group consisting of silver (Ag), gold (Au), and platinum (Pt), in which the silver (Ag), gold (Au), and platinum (Pt) are metal having a catalytic effect for silicon. Specifically, the coating process is an electron beam evaporation, a physical vapor deposition, a chemical vapor deposition, a sputtering, and so on. However, the present invention is not limited to be implemented in the above-mentioned coating processes. In the preferred embodiment, the metal layer is silver, and the predetermined thickness of the metal layer 20 is between 5 and 50 nanometers. In said thickness, the silver naturally forms regular porous structure on the surface 10 whose surface has the silicon material. Thus, the coating thickness of the metal layer 20 has to be controlled. If the thickness of the metal layer 20 is too thin, porous structures of silicon is finally formed instead of the silicon nanowire arrays. If the thickness of the metal layer 20 is too thick, an etching solution is difficult to seep into the metal layer 20, and it is difficult to form the silicon nanowire array with uniformity. In the preferred embodiment, the best thickness of the metal layer 20 is 20 nanometers.

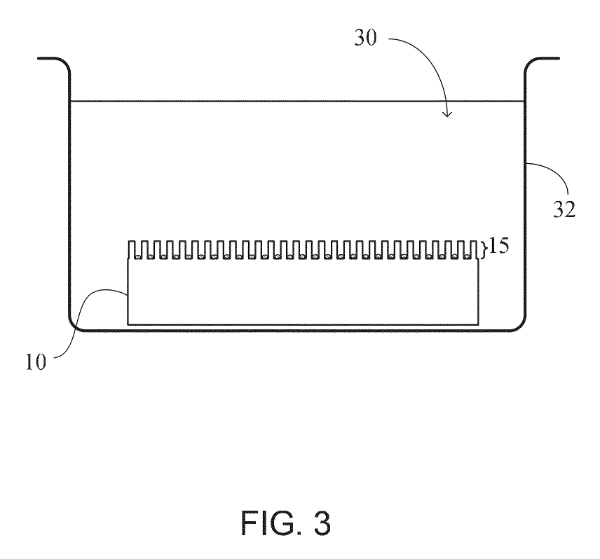

Referring to FIG. 1 and FIG. 3, FIG. 3 depicts a schematic cross-sectional diagram illustrating a substrate whose surface has a silicon material in performing step S20. A metal-induced chemical etching is performed for the silicon material by using an etching solution. In the preferred embodiment, the step S20 is to immerse the substrate 10 whose surface 10 has the silicon material in a container 32 with the etching solution 30 for processing a wet etching.

Specifically, the etching solution 30 is an aqueous solution of hydrogen fluoride (HF) and hydrogen peroxide (H₂O₂), that is, hydrofluoric acid is mixed with hydrogen peroxide. Because the thickness of the metal layer 20 is ultra thin (5 nm to 50 nm), the etching solution 30 can easily be infiltrated to the surface of the substrate 10. Furthermore, the substrate 10 is partially etched down through the catalyst of the silver at the area on which the silver is located, and the area uncovered by the silver is not etched down. The hydrogen peroxide (H₂O₂) is utilized to oxidize the silicon to form silicon dioxide (SiO₂), and then the hydrofluoric acid is utilized to etch the silicon dioxide (SiO₂), thereby etching down.

It is worth mentioning that the relation between the hydrogen fluoride (HF) and the hydrogen peroxide (H₂O₂) can also affect the patterns of the formed silicon nanowire arrays. For the metal layer 20 (silver), the ratio of the hydrogen fluoride within the solution of the hydrogen fluoride and the hydrogen peroxide is 0.7 to 0.99, that is, [HF]/([HF]+[H₂O₂]) is between 0.7 and 0.99, and a more uniform silicon nanowire array can be obtained.

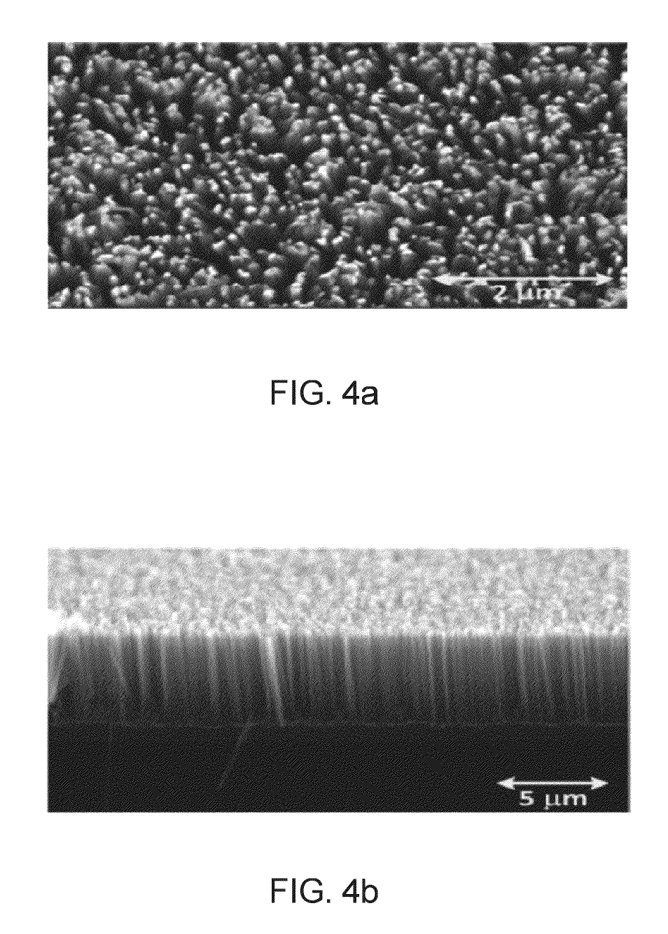

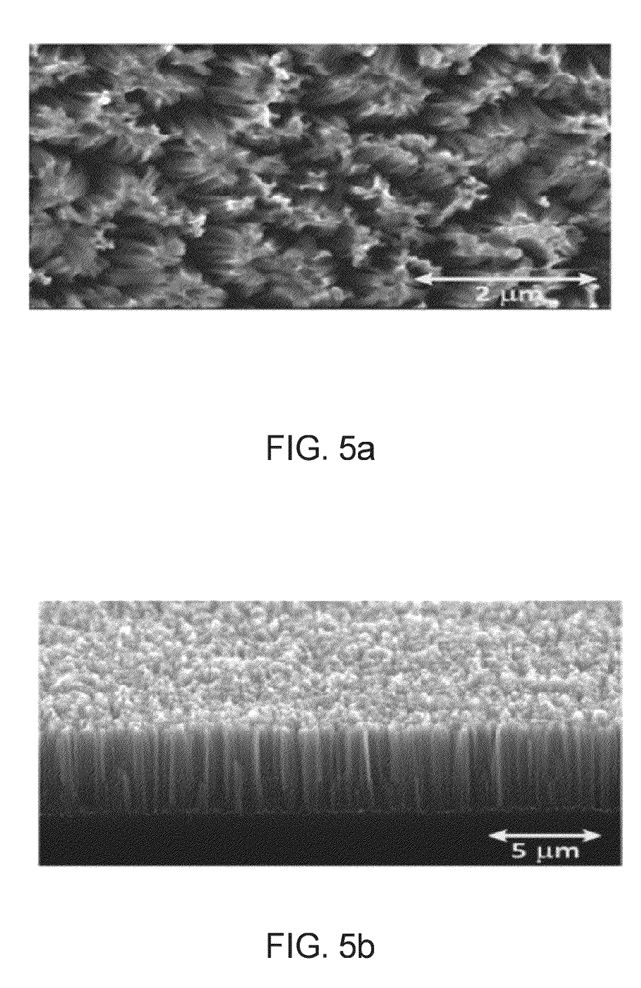

Referring to FIGS. 4a, 4b, 5a and 5b, FIG. 4a is a top view through an electron microscope illustrating a etched silicon nanowire array under the ratio of the hydrogen fluoride within the solution of the hydrogen fluoride and the hydrogen peroxide being 0.89; FIG. 4b is a side view of FIG. 4a; FIG. 5a is a top view through an electron microscope illustrating a etched silicon nanowire array under the ratio of the hydrogen fluoride within the solution of the hydrogen fluoride and the hydrogen peroxide being 0.68; FIG. 5b is a side view of FIG. 5a . In the preferred embodiment, it can be seen form experiment that the numerical value of [HF]/([HF]+[H₂O₂]) is between 0.87 and 0.95, and the more uniform silicon nanowire array can be obtained. As shown in FIG. 4a and FIG. 4b, the silicon nanowire array which is formed under the condition that [HF]/([HF]+[H₂O₂]) is 0.89 (between 0.87 and 0.95) is more uniform that the silicon nanowire array formed under the condition that [HF]/([HF]+[H₂O₂]1) is 0.68 (not between 0.87 and 0.95). In addition, the silicon nanowire array formed under the condition of [HF]/([HF]+[H₂O₂]) being 0.68 is easier to generate clustering.

In the preferred embodiment, a silicon etching rate is proportional to a temperature of the etching solution 30. That is to say, the higher the temperature of the etching solution 30 the stronger the etching effect becomes. There is a linear relationship between the etching rate and the temperature. Referring to FIG. 3 again, furthermore, the length 15 of the silicon nanowires is proportional to an etching time under a predetermined temperature. Accordingly, the length of the silicon nanowires can be estimated by computing the etching rate multiplied by the time.

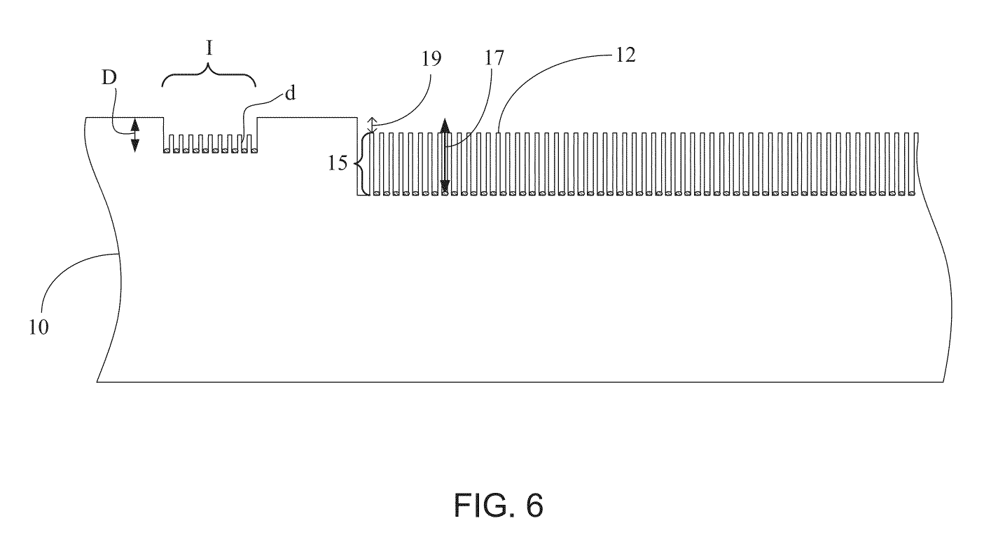

Referring to FIG. 6, in the preferred embodiment, the length 15 of the formed silicon nanowires 12 is smaller than or equal to an etching depth 17 of the silicon material. Specifically, in processing the metal-induced chemical etching, a little thickness of the silicon material is etched out first, and then the silicon nanowires 12 begin to be etched. In addition, the length 15 of the silicon nanowires 12 relates to an area of the metal layer 20 on the substrate 10. If the metal layer 20 is formed only on the area I, a difference between a depth d of the etched silicon nanowires 12 and a total etching depth D. That is, the smaller the area of the metal layer 20 on the substrate 10 is, the larger the difference between the length d of the silicon nanowires 12 and the total etching depth D is. In a predetermined etching time, the length d of the silicon nanowire 12 formed within the area I is smaller than the length 15 of the silicon nanowires 12 formed on an open space.

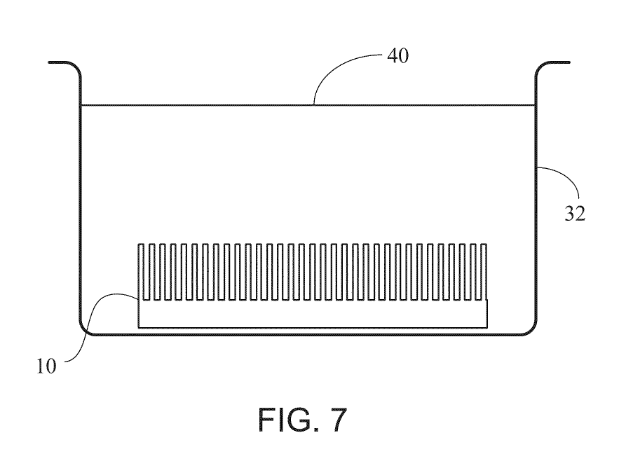

Referring to FIG. 1 and FIG. 7, FIG. 7 depicts a schematic cross-sectional diagram illustrating a substrate whose surface has a silicon material in performing step S30. At step S30, the metal layer 20 is rinsed from the substrate. For example, the remaining silver can be washed away by using nitric acid (HNO₃) for forming the clean silicon nanowire array with a large area and uniform arrangement.

In summary, according to the fabricating method of the silicon nanowire arrays of the present invention, the conventional method for depositing the nano silver particles on the surface of the silicon substrate can be replaced by using the coating process to coat a ultra-thin silver layer for the silver naturally forming porous structure on the substrate whose surface has the silicon material. Then the metal-induced chemical etching is performed for the silicon nanowire arrays with a large area and uniform arrangement being etched out. Therefore, the present invention overcomes the drawbacks of nonuniformity, collapse, and clustering occurred on the silicon nanowire arrays formed by using the nano silver particals to perform the metal-induced chemical etching. The surface consisting of the silicon nanowire arrays with uniform arrangement has a very low reflection, thereby enhancing light absorption thereof.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A method for fabricating silicon nanowire arrays, comprising:
forming a metal layer with a predetermined thickness on a substrate whose surface has a silicon material by a coating process, the metal layer selected from the group consisting of silver, gold and platinum;
performing a metal-induced chemical etching for the silicon material by using an etching solution; and
rinsing the metal layer from the substrate.

2. The method for fabricating silicon nanowire arrays of claim 1 wherein the coating process is an electron beam evaporation, a physical vapor deposition, a chemical vapor deposition, or a sputtering.

3. The method for fabricating silicon nanowire arrays of claim 1 wherein the substrate whose surface has the silicon material is a silicon substrate, a silicon substrate whose surface has a thin silicon film, or a substrate whose surface has the thin silicon film.

4. The method for fabricating silicon nanowire arrays of claim 3 wherein the silicon material is monocrystalline silicon, polycrystalline silicon or amorphous silicon, and the silicon material is intrinsic silicon or doped silicon.

5. The method for fabricating silicon nanowire arrays of claim 1 wherein the metal layer is silver.

6. The method for fabricating silicon nanowire arrays of claim 5 wherein the predetermined thickness is between 5 and 50 nanometers.

7. The method for fabricating silicon nanowire arrays of claim 1 wherein the etching solution is an aqueous solution of hydrogen fluoride and hydrogen peroxide.

8. The method for fabricating silicon nanowire arrays of claim 7 wherein a ratio of the hydrogen fluoride within the solution of the hydrogen fluoride and the hydrogen peroxide is 0.7 to 0.99.

9. The method for fabricating silicon nanowire arrays of claim 1 wherein a silicon etching rate is proportional to a temperature of the etching solution, and a length of silicon nanowires is proportional to an etching time under a predetermined temperature.

10. The method for fabricating silicon nanowire arrays of claim 1 wherein the smaller an area of the metal layer on the silicon material is, the larger a difference between a length of the silicon nanowires and a total etching depth is, and a etching rate of forming the silicon nano wires also decreases.
